(19) United States
(12) Patent Application Publication
(10) Pub. No.: US 2023/0340693 A1
(43) Pub. Date: Oct. 26, 2023

(54) SINGLE-CRYSTAL METAL FILM BY SOLID-STATE CRYSTAL GROWTH OF SEED CRYSTALS, LARGE-AREA SINGLE-LAYER OR MULTILAYER GRAPHENE WITH ADJUSTED ORIENTATION ANGLE USING SAME, AND METHOD FOR MANUFACTURING SAME

(71) Applicant: IUCF-HYU (INDUSTRY-UNIVERSITY COOPERATION FOUNDATION HANYANG UNIVERSITY), Seoul (KR)

(72) Inventors: Ho Bum PARK, Seoul (KR); Ji Soo ROH, Seoul (KR); Jun Kyu JANG, Seoul (KR)

(21) Appl. No.: 17/769,404

(22) PCT Filed: Oct. 20, 2020
(86) PCT No.: PCT/KR2020/014289

§ 371 Date: Apr. 15, 2022

(30) Foreign Application Priority Data
Oct. 21, 2019 (KR) 10-2019-0130795
Jul. 28, 2020 (KR) 10-2020-0093904

(51) Int. Cl. C30B 29/02; C01B 32/186; H01B 1/02; C30B 1/02; C30B 25/18; C22F 1/02; C22F 1/08

(52) U.S. Cl. CPC C30B 29/02; C01B 32/186; H01B 1/02; C30B 1/02; C30B 25/18; C22F 1/02; C22F 1/08

(57) ABSTRACT

The present disclosure manufactures a single-crystal metal film oriented only in the (111) crystal plane by bringing seed crystals comprising (111) oriented seeds or (111) single-crystalline seed crystals into contact with a polycrystalline metal precursor and performing heat treatment, thereby manufacturing a single-crystal metal film oriented only in the (111) crystal plane with a high single crystallization rate irrespective of the thickness and shape of the polycrystalline metal precursor. Additionally, the present disclosure obtains a large-area single-crystal metal film with adjusted orientation angle by introducing single-crystal seed crystals into a polycrystalline metal film at a predetermined angle of rotation and performing heat treatment, and manufactures large-area single-layer graphene with adjusted orientation angle using the same, and multilayer graphene with adjusted orientation angle between graphene by stacking the single-layer graphene.

### TECHNICAL FIELD

The present disclosure relates to a single-crystal metal film by solid-state crystal growth of seed crystals, a large-area single-layer or multilayer graphene with adjusted orientation angle using the same and a method for manufacturing the same, and more particularly, to technology that manufactures a single-crystal metal film oriented only in the (111) crystal plane by bringing seed crystals comprising (111) oriented seeds or (111) single-crystalline seed crystals into contact with a polycrystalline metal precursor and performing heat treatment, obtains a large-area single-crystal metal film with adjusted orientation angle by introducing single-crystal seed crystals into a polycrystalline metal film at a predetermined angle of rotation and performing heat treatment, and manufactures large-area single-layer or multilayer graphene with adjusted orientation angle using the same.

### BACKGROUND ART

Single-crystal metals have superior electrical and optical properties over polycrystalline metals and therefore are used in electronic and optical device applications, and there is a fast increasing demand for single-crystal metals as substrates for synthesis of high quality single-crystal two-dimensional (2D) nanomaterials.

A melt growth method or a deposition method has been used to manufacture single-crystal metal films, but these methods require high production cost and have low productivity. Accordingly, there are recently developed methods for single crystallization by crystal growth induced through heat treatment of polycrystalline metal substrates at high temperature using a variety of heat treatment methods, for example, repeated heat treatment, dynamic heat treatment or heat treatment after oxide layer formation, and most of them need special equipment, specific metal films and long processing time and have low repeatability and reproducibility.

Some prior art documents about the manufacture of single-crystal metal films disclose crystallization of a metal thin film layer (Cu) by heat-treating the metal thin film layer (Cu) on a substrate under the conditions of 800 to 1000° C. and 1 to 760 torr with an addition of a mixed hydrogen/argon gas, but the metal thin film layer is formed on the substrate such as a silicon wafer and does not have a single-crystal structure oriented only in the (111) crystal plane.

Additionally, they disclose methods for manufacturing a single-crystal metal film oriented only in the (111) crystal plane by heat-treating a polycrystalline metal precursor (Cu) under the hydrogen atmosphere conditions of 900 to 1,600° C. and 1 mtorr to 300,000 torr, but beyond certain thickness, the single crystallization rate significantly reduces.

Additionally, they disclose the growth of a 100 nm thick single-crystal copper film on a MgO substrate by an ultrahigh vacuum magnetron sputtering deposition method, but the expensive MgO substrate is still used, and the metal film is not oriented only in the (111) crystal plane and has various crystal planes.

Additionally, technology that grows a 170 nm thick (111) oriented single-crystal nickel film on a sapphire substrate by an ultrahigh vacuum laser ablation deposition method is known, but the expensive sapphire substrate is still used, and the ultrahigh vacuum laser ablation deposition method makes mass production and the manufacture of large-area single-crystal metal films difficult due to its complicated process.

Additionally, studies about single crystallization of various metal films, for example, copper, have focused on efficient production of large-area products for decades in the applications of electronic and optical devices and high quality nanomaterial synthetic substrates. As a result, methods for efficiently producing single-crystal metal films by heat-treating low cost polycrystalline metal substrates by a variety of methods have been developed. Among them, approaches for the growth of crystals are primarily used since they are the most thermodynamically stable, and it is possible to predict the plane directions of most of single-crystal metal film surfaces (for example, in the case of Cu, (111)). However, it is impossible to predict or adjust how the (111) crystal is rotated and the orientation angle. The high quality 2D nanomaterials grown along the crystallographic axis of the metal substrate may greatly change in the properties along the orientation angle when stacked, and thus it is very important to adjust the orientation angle.

Meanwhile, there have been reports about methods for making single-crystal metal alloys through directional coagulation using seed crystals. When seed crystals having known orientation are heat-treated in contact with a mold used to produce the alloy, the seed crystals partially melt and the orientation moves to the crystal planes, thereby adjusting the primary orientation and secondary orientation of the alloy, and through this, controlling the mechanical properties.

Recently, some studies have reported that in the synthesis of double-layer graphene by stacking graphene, unique electrical properties are identified by adjusting misorientation between two graphene. It is known that when double-layer graphene is stacked with 1.1° misorientation, isolated low energy bands are induced and tunable superconducting and insulating phases appear.

However, since the existing seed crystal-introduced single-crystal growth methods use seed crystals comprising unknown (111) oriented crystals or (111) crystals, it is impossible to predict the orientation angle of the single-crystal substrates formed after heat treatment. To shift the orientation of the seed crystals through the crystal planes, it is necessary to increase the temperature near the melting temperatures of the alloys, but in this instance, due to a phenomenon in which the crystal planes deviate from their positions, the yield of the single-crystal metal alloys is very low, and it takes high costs to produce defect-free seed crystals with adjusted orientation.

Additionally, most of studies about orientation angle adjustment in the stack of graphene have been conducted towards methods for delaminating and stacking high quality graphite having one orientation angle. In this case, it is impossible to produce multilayer nanomaterials with adjusted orientation angle in large quantities over a large area. Moreover, when using graphene by a chemical vapor deposition (CVD) method, the orientation of the graphene cannot be known until analysis is completed after synthesis or stack.

Accordingly, the inventors completed the present invention with an idea about manufacturing a single-crystal metal film oriented only in the (111) crystal plane with a high single crystallization rate irrespective of the thickness and shape of a polycrystalline metal precursor by bringing seed crystals comprising (111) oriented seeds or (111) single-crystalline seed crystals into contact with the polycrystalline metal precursor and performing heat treatment, and manufacturing large-area single-layer or multilayer graphene with adjusted orientation angle using a large-area single-crystal metal film with adjusted orientation angle obtained by introducing single-crystal seed crystals into a polycrystalline metal film at a predetermined angle of rotation and performing heat treatment.

### RELATED LITERATURES

### Patent Literature

Patent Literature 1. Korean Patent No. 10-1132706
Patent Literature 2. Korean Patent No. 10-1767242
Patent Literature 3. Korean Patent No. 10-1986788
Patent Literature 4. Japanese Patent Publication No. 2004-262684

### Non-Patent Literature

Non-Patent Literature 1. J. M. Purswani et al., Thin Solid Films 515, 1166-1170 (2006)
Non-Patent Literature 2. IV. Malikov et al., Thin Solid Films 519, 527-535 (2010)

### DISCLOSURE

### Technical Problem

The present disclosure is designed to solve the above-described problem, and therefore the present disclosure is directed to manufacturing a single-crystal metal film oriented only in the (111) crystal plane with a high single crystallization rate irrespective of the thickness and shape of a polycrystalline metal precursor by bringing seed crystals comprising (111) oriented seeds or (111) single-crystalline seed crystals into contact with the polycrystalline metal precursor and performing heat treatment.

Additionally, the present disclosure is further directed to obtaining a large-area single-crystal metal film with adjusted orientation angle by introducing single-crystal seed crystals into a polycrystalline metal film at a predetermined angle of rotation and performing heat treatment, and providing large-area single-layer or multilayer graphene with adjusted orientation angle using the same and a method for manufacturing the same.

### Technical Solution

To achieve the above-described object, the present disclosure provides a single-crystal metal film with seed crystals comprising (111) oriented seeds or (111) single-crystalline seed crystals embedded therein.

The single-crystal metal film may include any one selected from copper (Cu), nickel (Ni), cobalt (Co), iron (Fe), ruthenium (Ru), platinum (Pt), palladium (Pd), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr).

Additionally, the present disclosure provides a conductive film comprising the single-crystal metal film.

Additionally, the present disclosure provides a substrate for growth of two-dimensional nanomaterials comprising the single-crystal metal film.

Additionally, the present disclosure provides a method for manufacturing a single-crystal metal film by solid-state crystal growth of seed crystals, comprising (a) preparing a polycrystalline metal precursor having various crystal plane orientations such that the crystal planes are not oriented in any one direction, and (b) bringing seed crystals comprising (111) oriented seeds or (111) single-crystalline seed crystals into contact with a surface of the metal precursor of the step (a) and performing heat treatment.

The seed crystals comprising (111) oriented seeds or the (111) single-crystalline seed crystals may be brought into contact with one or two surfaces of the polycrystalline metal precursor and then pressed against a substrate.

Two or more seed crystals comprising (111) oriented seeds or two or more (111) single-crystalline seed crystals may be brought into contact.

The heat treatment of the step (b) may be performed at 800 to 1500° C.

Additionally, the present disclosure provides a method for manufacturing a single-crystal metal film by solid-state crystal growth of seed crystals, comprising (A) attaching seed crystals comprising (111) oriented seeds or (111) single-crystalline seed crystals to a surface of a polycrystalline metal film moving in a roll-to-roll continuous process; and (B) heat-treating the moving polycrystalline metal film having undergone the step (A), wherein the polycrystalline metal film of the step (A) has various crystal plane orientations such that the crystal planes are not oriented in any one direction.

Additionally, the present disclosure provides large-area single-layer or multilayer graphene with adjusted orientation angle, grown on a single-crystal metal film with adjusted orientation angle having specific crystal orientation.

The single-crystal metal film may be 15 μm or more in thickness.

Additionally, the present disclosure provides a method for manufacturing large-area single-layer graphene with adjusted orientation angle, comprising (I) introducing single-crystal seed crystals having specific crystal orientation into a polycrystalline metal film at a predetermined angle of rotation and performing heat treatment to obtain a single-crystal metal film with adjusted orientation angle; and (II) growing graphene on the single-crystal metal film with adjusted orientation angle.

The heat treatment of the step (I) may comprise increasing temperature to 800 to 1200° C. at a temperature rise rate of 10 to 50° C./min under an argon gas atmosphere of 100 to 500 sccm and less than 2 torr, and maintaining isothermal condition at the increased temperature for 1 to 4 hours under a hydrogen gas atmosphere of 100 to 500 sccm and 1 torr or more.

The graphene growth of the step (II) may be performed by maintaining isothermal condition under 0.1 torr or more at 800 to 1080° C. for 10 minutes to 4 hours under a hydrogen gas atmosphere of 0 to 1000 sccm and a methane gas atmosphere of 1 to 10 sccm.

Additionally, the present disclosure provides multilayer graphene with adjusted orientation angle between graphene by stacking the single-layer graphene manufactured by the above-described method.

### Advantageous Effects

According to the present disclosure, it is possible to manufacture a single-crystal metal film oriented only in the (111) crystal plane with a high single crystallization rate irrespective of the thickness and shape of a polycrystalline metal precursor by bringing seed crystals comprising (111) oriented seeds or (111) single-crystalline seed crystals into contact with the polycrystalline metal precursor and performing heat treatment.

Additionally, it is possible to obtain a large-area single-crystal metal film with adjusted orientation angle by introducing single-crystal seed crystals into a polycrystalline metal film at a predetermined angle of rotation and performing heat treatment, and provide large-area single-layer graphene with adjusted orientation angle using the same and multilayer graphene with adjusted orientation angle between graphene by stacking the single-layer graphene.

### DESCRIPTION OF DRAWINGS

FIG. 1 shows the number of (111) oriented seed crystals and their crystal structure as a function of thickness of a cold-rolled copper foil.

FIG. 2(A) is an image showing the crystal structure in normal grain growth and abnormal grain growth occurred in a 15 μm thick copper foil after heat treatment from comparative example 1 of the present disclosure, and FIG. 2(B) shows a result of comparing the single crystallization rate in a 10 μm thick copper foil and a 30 μm thick copper foil heat-treated in the same condition as comparative example 1.

FIG. 3(A) is an image showing seed crystals comprising (111) oriented seeds embedded in a single-crystal metal film according to the present disclosure, and FIG. 3(B) is an image showing (111) single-crystalline seed crystals.

FIGS. 4(A) to 4(D) show contact methods of seed crystals according to an embodiment of the present disclosure, and FIG. 4(E) shows the single crystallization rate of a single-crystal metal film heat-treated according to the type of seed crystals and the contact method on a 15 m thick cold-rolled copper foil.

FIG. 5 shows a result of comparing the single crystallization rate in a single-crystal metal film manufactured from example 3 of the present disclosure and a 10 μm thick copper foil and a 30 μm thick copper foil heat-treated in the same condition as example 3.

FIG. 6(A) shows the single crystallization rate as a function of the number of seed crystals, and FIG. 6(B) shows the single crystallization rate as a function of the size of the seed crystal, in the process of manufacturing a single-crystal metal film from example 2 of the present disclosure.

FIG. 7 is a diagram showing a method for manufacturing a single-crystal metal film by solid-state crystal growth of seed crystals through a roll-to-roll continuous process according to an embodiment of the present disclosure.

FIG. 8 an image showing electron backscatter diffraction (EBSD) and crystal orientation of a single-crystal copper film manufactured by introducing single-crystal seed crystals into a polycrystalline copper film and performing heat treatment according to example 4 of the present disclosure.

FIG. 9 shows (111) standard stereographic projection of a single-crystal metal film.

FIG. 10 shows an EBSD image and a pole figure of the boundary including some of single-crystal seed crystals and parts of a single-crystallized copper film according to example 4 of the present disclosure.

FIG. 11 is a pole figure showing seed crystals introduced at a predetermined angle of rotation when a single-crystal copper film is divided into pieces and used as seed crystals according to example 4 of the present disclosure.

FIG. 12 is an image showing 9 pieces divided to identify the crystal orientation of a single-crystallized copper film according to example 4 of the present disclosure.

FIG. 13 is a pole figure showing the crystal orientation of the single-crystallized copper film divided into 9 pieces in FIG. 5.

FIG. 14 is an optical electron microscope image showing 9 divided pieces after the growth of graphene on a single-crystal metal film with adjusted orientation angle according to example 4 of the present disclosure.

FIG. 15 is an image showing the orientation of a copper film having undergone single crystallization after the introduction of seed crystals having single crystal orientation by 45°, −45° rotation according to example 4 of the present disclosure.

### BEST MODE

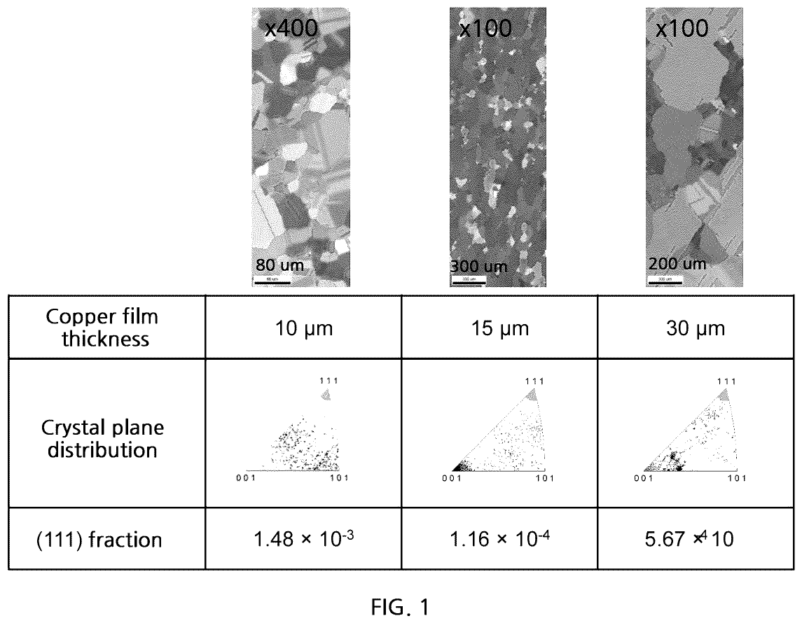

Due to the existing metal film manufacturing methods including the rolling process, metal films of a face-centered cubic structure have (100), (110) dominant oriented surface structures after recrystallization, and the fraction of (111) oriented crystals that can be grown to large crystals due to thermodynamic stability is very low. As shown in FIG. 1, in general, thick copper films are more difficult to include (111) plane of crystals in the same area.

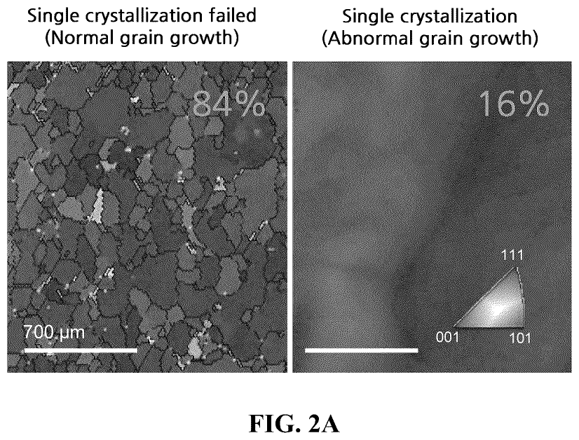

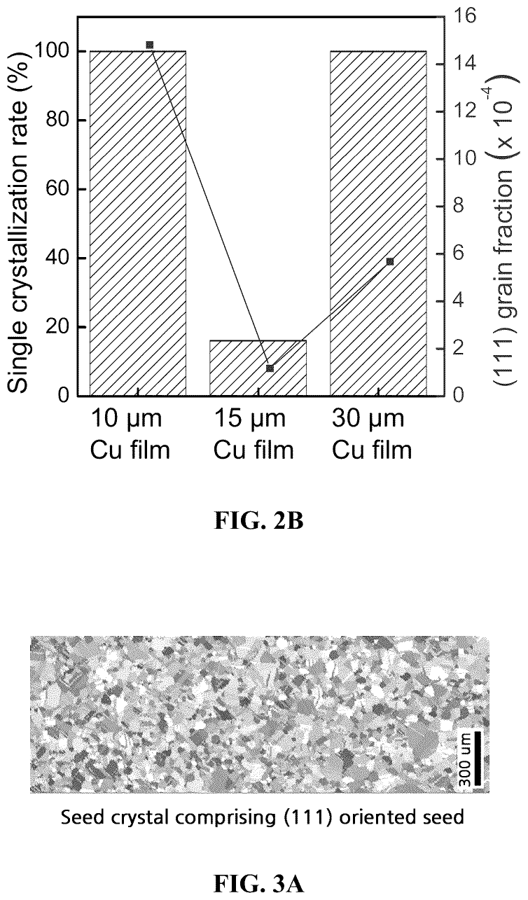

Additionally, FIG. 2(A) shows the crystal structure when single crystallization, i.e., abnormal grain growth occurred in the cold-rolled copper film after heat treatment, and when abnormal grain growth did not occur. When single crystallization does not occur and only normal grain growth occurs, a polycrystalline structure with (100) dominant orientation is formed, while when the thermodynamically stable (111) oriented crystals are grown abnormally fast, a single crystal structure with (111) orientation is obtained, and thus grain growth through heat treatment occurs, but the single crystallization rate and reproducibility is still low.

To solve the above-described problem, the present disclosure determines that single crystallization occurs probabilistically in spite of heat treatment in the same condition due to the absence of thermodynamically stable (111) oriented crystals for abnormal grain growth of single crystals in a metal film, and introduces (111) oriented seed crystals into a polycrystalline metal film, thereby forming a single-crystal metal film oriented only in the (111) crystal plane irrespective of the thickness of the polycrystalline metal film.

That is, the present disclosure provides a single-crystal metal film with seed crystals comprising (111) oriented seeds or (111) single-crystalline seed crystals embedded therein.

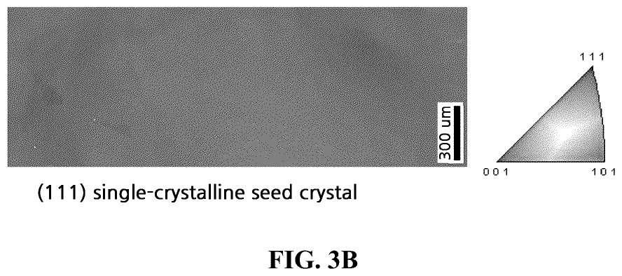

As shown in FIG. 3, the seed crystals may be seed crystals comprising (111) oriented seeds formed by cold rolling (FIG. 3A), or (111) single-crystalline seed crystals through heat treatment (FIG. 3B).

The seed crystals comprising (111) oriented seeds or the (111) single-crystalline seed crystals may include any one selected from copper (Cu), nickel (Ni), cobalt (Co), iron (Fe), ruthenium (Ru), platinum (Pt), palladium (Pd), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr), and specifically, may be copper (Cu), but is not limited thereto.

The seed crystals comprising (111) oriented seeds or the (111) single-crystalline seed crystals may be formed irrespective of the shape, and may be in any shape including foil, flat plate, block or tube shapes, but specifically, may be in the shape of a foil.

The single-crystal metal film may include any one selected from copper (Cu), nickel (Ni), cobalt (Co), iron (Fe), ruthenium (Ru), platinum (Pt), palladium (Pd), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr), and specifically, may be copper (Cu), but is not limited thereto.

The single-crystal metal film may be formed irrespective of the shape, and may be in any shape including foil, flat plate, block or tube shapes, but specifically, may be in the shape of a foil.

The thickness of the single-crystal metal film may be 1 to 100 μm, specifically 5 to 50 μm, and more specifically 10 to 30 μm. It is found that the existing copper film having the thickness of 15 μm or more has a low single crystallization rate even after it is heat-treated, while the single-crystal metal film with seed crystals embedded therein according to the present disclosure has a very high single crystallization rate even when its thickness is 15 μm or more.

Additionally, the present disclosure provides a conductive film including the single-crystal metal film according to the present disclosure.

Additionally, the present disclosure provides a substrate for growth of two-dimensional (2D) nanomaterials including the single-crystal metal film according to the present disclosure.

Additionally, the present disclosure provides a method for manufacturing a single-crystal metal film by solid-state crystal growth of seed crystals, including (a) preparing a polycrystalline metal precursor having various crystal plane orientations such that the crystal planes are not oriented in any one direction, and (b) bringing seed crystals comprising (111) oriented seeds or (111) single-crystalline seed crystals into contact with the surface of the metal precursor of the step (a) and performing heat treatment.

First, as the present disclosure provides the single-crystal metal film by maximizing the grain growth of (111) crystal plane of single crystals through recrystallization and abnormal grain growth by bringing the seed crystals into contact with the polycrystalline metal precursor and performing heat treatment, the polycrystalline metal precursor having various crystal plane orientations such that the crystal planes are not oriented in any one direction is prepared as the metal precursor for forming the single-crystal metal film.

The polycrystalline metal precursor having various crystal plane orientations may include any one selected from copper (Cu), nickel (Ni), cobalt (Co), iron (Fe), ruthenium (Ru), platinum (Pt), palladium (Pd), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr), and the shape of the metal precursor may be any shape including foil, flat plate, block or tube shapes, but to form the uniform single-crystal metal film by heat treatment, specifically, the metal precursor may be in the form of a foil, and in particular, more specifically, a commercially available copper foil that is easy to obtain and has a low price may be used.

Additionally, the thickness of the commercially available copper foil may be 1 to 100 μm, specifically 5 to 50 μm, and more specifically 10 to 30 μm. It is found that the existing copper film having the thickness of 15 μm or more has a low single crystallization rate even after it is heat-treated, while the single-crystal metal film with seed crystals embedded therein according to the present disclosure has a very high single crystallization rate even when its thickness is 15 μm or more.

The seed crystals comprising (111) oriented seeds or the (111) single-crystalline seed crystals may include any one selected from copper (Cu), nickel (Ni), cobalt (Co), iron (Fe), ruthenium (Ru), platinum (Pt), palladium (Pd), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir), and zirconium (Zr), and moreover, the shape may be any shape including foil, flat plate, block or tube shapes, but to form the uniform single-crystal metal film by heat treatment, specifically, the shape may be a foil shape, and in particular, more specifically, a commercially available copper foil that is easy to obtain and has a low price may be used.

Additionally, the thickness of the seed crystals comprising (111) oriented seeds or the (111) single-crystalline seed crystals may be 1 to 100 μm, specifically 5 to 50 μm, and more specifically 10 to 20 μm, but is not limited thereto.

Additionally, the polycrystalline metal precursor having various crystal plane orientations is in the shape of a foil, and the seed crystals comprising (111) oriented seeds or the (111) single-crystalline seed crystals may be brought into contact with one or two surfaces of the foil, and after the seed crystals comprising (111) oriented seeds or the (111) single-crystalline seed crystals are brought into contact with one or two surfaces of the polycrystalline metal precursor, the seed crystals may be pressed against a substrate.

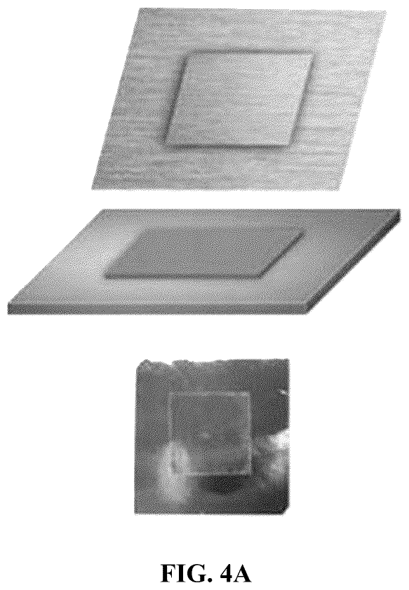

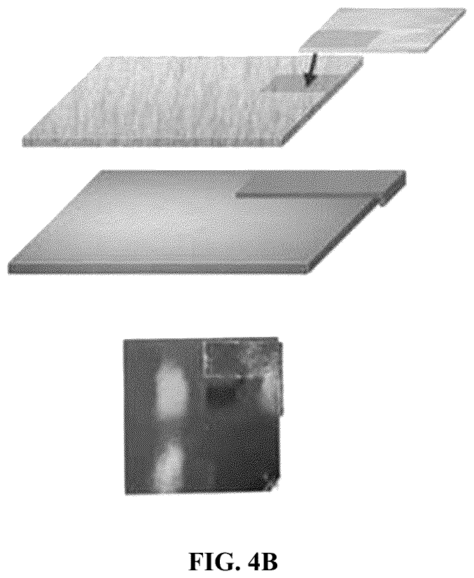

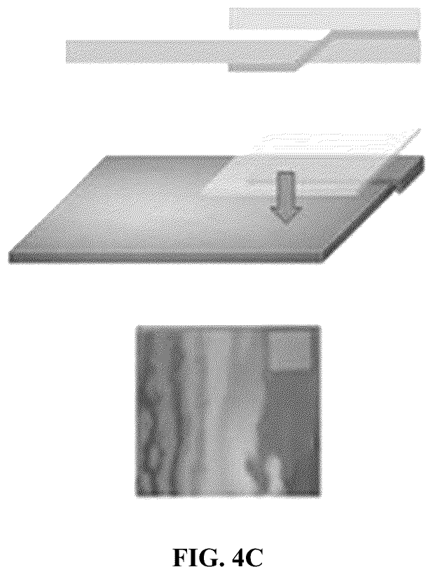

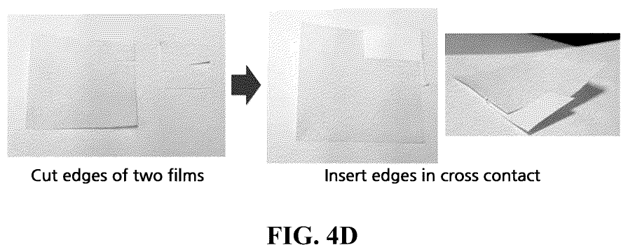

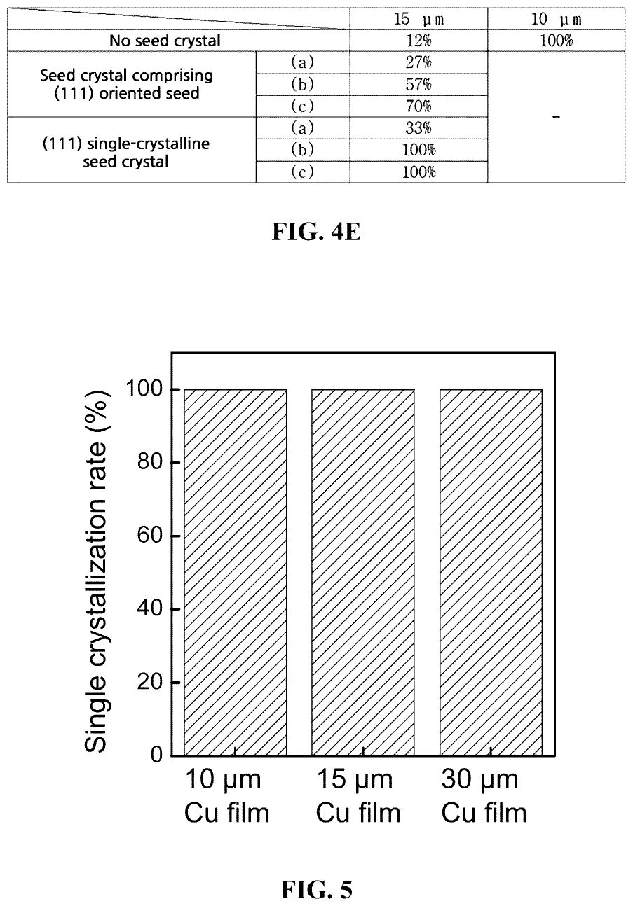

For diffusion of (111) oriented crystals in the polycrystalline metal film from the seed crystals in contact with the polycrystalline metal film, the contact between the polycrystalline metal film and the seed crystals is important, and as shown in FIG. 4, the contact may be made by three methods, but is not limited thereto. Specifically, as shown in FIG. 4(C), the contact rate may be improved by pressing the seed crystals in contact with the polycrystalline metal film against the substrate. The substrate may include any type of substrate that improves the contact rate between the polycrystalline metal film and the seed crystals by pressing the seed crystals irrespective of the type. In particular, the single crystallization rate when the seed crystals are brought into contact with two surfaces of the polycrystalline metal precursor (FIG. 4(B)) is higher than the single crystallization rate when the seed crystals are brought into contact with one surface of the polycrystalline metal precursor (FIG. 4(A)), and the single crystallization rate when the seed crystals are brought into contact with one or two surfaces of the polycrystalline metal precursor and then pressed (FIG. 4(C)) is much higher than the single crystallization rate when the seed crystals are brought into contact with two surfaces of the polycrystalline metal precursor (FIG. 4(B)).

Additionally, two or more seed crystals comprising (111) oriented seeds or two or more (111) single-crystalline seed crystals may contact the polycrystalline metal precursor surface. The number of seed crystals in contact with the polycrystalline metal precursor surface is a parameter that affects the single crystallization rate, and as the number of seed crystals increases, the single crystallization rate tends to improve.

Additionally, the seed crystals comprising (111) oriented seeds contain the (111) oriented seeds at the fraction of 10⁻⁴ to 10⁻¹ based on the total seed crystal area, or the (111) single-crystalline seed crystals may contact at the fraction of 10⁻⁴ to 2⁻¹ based on the area of the polycrystalline metal precursor. That is, it is found that the fraction of the seed crystals in contact is very small based on the area of the polycrystalline metal precursor, but nevertheless, single crystallization may occur at a high rate.

Subsequently, the heat treatment of the step (b) may be performed at 800 to 1500° C. Specifically, the heat treatment may be performed by increasing the temperature at the rate of 10 to 50° C./min, more specifically 20 to 40° C./min, and even more specifically 25 to 35° C./min while maintaining the pressure in a chamber at 0.01 to 100 torr, specifically 0.1 to 10 torr, and more specifically 0.4 to 1 torr in the chamber under an argon atmosphere in which argon flows at the flow rate of 10 to 1,000 sccm, specifically 50 to 500 sccm, and more specifically 80 to 200 sccm, and when the temperature reaches the heat treatment temperature of 800 to 1500° C., more specifically 900 to 1300° C., and even more specifically 1000 to 1100° C., maintaining the isothermal condition at the heat treatment temperature under a hydrogen gas atmosphere for 10 minutes to 10 hours, more specifically 1 to 8 hours, and even more specifically 1 to 3 hours. The heat treatment may be performed in the chamber in which the hydrogen gas flows at the flow rate of 1 to 1000 sccm, specifically 50 to 800 sccm, and more specifically 100 to 500 sccm while maintaining the pressure in the chamber at 0.01 to 100 torr, specifically 0.1 to 10 torr, and more specifically 1 to 5 torr. The gas type, temperature rise rate, heat treatment temperature and heat treatment temperature maintenance time conditions are all important for the heat treatment process, and outside of the ranges of the conditions in which the temperature rises at the rate of 10 to 50° C./min under the argon atmosphere and reaches the heat treatment temperature of 800 to 1500° C. and then the isothermal condition is maintained for 10 minutes to 10 hours under the hydrogen atmosphere, the single-crystal metal film oriented only in the (111) crystal plane is not formed. Accordingly, the present disclosure forms the single-crystal metal film oriented only in the (111) crystal plane by crystallization of the metal precursor with the adjusted process parameters for the heat treatment of the step (b) in the above-described range.

In the end, the present disclosure is fundamentally different in technical spirit from formation of a single-crystal metal film on an existing single-crystal substrate or formation of a polycrystalline metal film by heat treatment of a metal precursor without a substrate, and compared to the formation of a single-crystal copper film using an existing copper foil precursor of 1 cm×1 cm in size, the present disclosure can manufacture a large-area single-crystal metal film irrespective of the size and thickness of the metal precursor by bringing seed crystals into contact with the metal precursor having any size and any thickness and performing heat treatment, thereby achieving commercialization by mass production.

Meanwhile, the present disclosure obtains the single-crystal metal film when the heat treatment process of the step (b) is completed, but if necessary, after the heat treatment process, a natural cooling or artificial cooling step may be further included, and the artificial cooling step is preferably performed slowly at the cooling rate of 10 to 50° C./min. In particular, when cooling is performed fast beyond the above-described cooling rate range, cracks may occur in the single-crystal metal film while single crystals are uniformly grown and arranged in ordered array, so caution is required. Moreover, to prevent an oxidizing atmosphere in the cooling step, the cooling may be performed while injecting hydrogen at 10 to 1,000 sccm, specifically 50 to 500 sccm, and more specifically 80 to 200 sccm, and the cooling may be performed under the pressure in the chamber of 1 to 100 torr, specifically 3 to 50 torr.

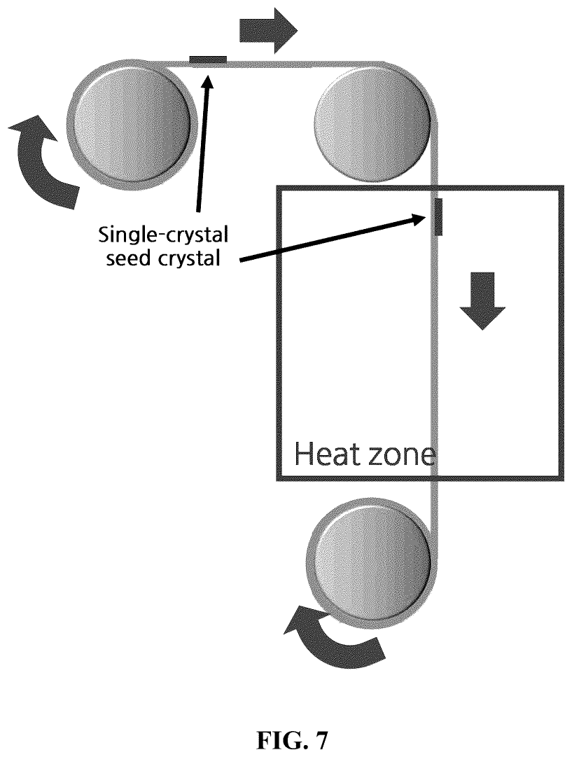

Additionally, as shown in FIG. 7, the present disclosure provides a method for manufacturing a single-crystal metal film by solid-state crystal growth of seed crystals, including (A) attaching seed crystals comprising (111) oriented seeds or (111) single-crystalline seed crystals to the surface of a polycrystalline metal film moving in a roll-to-roll continuous process, and (B) heat-treating the moving polycrystalline metal film having undergone the step (A), wherein the polycrystalline metal film of the step (A) has various crystal plane orientations such that the crystal planes are not oriented in any one direction.

Specifically, the single-crystal metal film is provided by attaching the seed crystals comprising (111) oriented seeds or the (111) single-crystalline seed crystals to the surface of the polycrystalline metal film in the process of transferring the polycrystalline metal film wound on the roller, and maximizing the grain growth of the (111) crystal plane of single crystals by recrystallization and abnormal grain growth through sufficient heat treatment while passing through the heat zone. It is possible to manufacture a large-area single-crystal metal film through the roll-to-roll continuous process, thereby achieving commercialization by mass production.

In addition, the present disclosure adjusts the orientation angle of the metal film having specific crystal orientation by introduction of single-crystal seed crystals and heat treatment to cause single crystallization. Additionally, it is possible to synthesize graphene with adjusted orientation using the same as a substrate for growth, and through this, adjust misorientation when stacking the graphene.

An embodiment of the present disclosure uses a (111) oriented single-crystal copper film having a known orientation angle as single-crystal seed crystals, brings it into contact with a polycrystalline metal film in which single crystallization is unlikely to occur by a variety of methods and then induces single crystallization through heat treatment, and thus identifies that the single-crystal metal film has the same crystal orientation as the introduced single-crystal seed crystals.

Additionally, since the size of the single-crystal seed crystals necessary for single crystallization is small, the single-crystal orientation angle after heat treatment may be adjusted by cutting a large single-crystal film of which the orientation angle is analyzed and introducing the pieces at a predetermined angle of rotation, and, single-crystal graphene with adjusted or known orientation angle may be synthesized using the same.

Therefore, the present disclosure provides large-area single-layer or multilayer graphene with adjusted orientation angle grown on the single-crystal metal film with adjusted orientation angle having specific crystal orientation such as (111) crystal plane orientation.

The single-crystal metal film may include any one selected from copper (Cu), nickel (Ni), cobalt (Co), iron (Fe), ruthenium (Ru), platinum (Pt), palladium (Pd), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr).

Additionally, the thickness of the single-crystal metal film may be 1 to 100 μm, specifically 5 to 50 μm, and more specifically 10 to 30 μm. In particular, the existing copper film having the thickness of 15 μm or more has a low single crystallization rate even after it is heat-treated, while the single-crystal metal film with single-crystal seed crystals seeded therein according to the present disclosure has a very high single crystallization rate even when its thickness is 15 μm or more.

Additionally, the present disclosure provides a method for manufacturing large-area single-layer graphene with adjusted orientation angle, including (I) introducing single-crystal seed crystals having specific crystal orientation into a polycrystalline metal film at a predetermined angle of rotation and performing heat treatment, to obtain a single-crystal metal film with adjusted orientation angle; and (II) growing graphene on the single-crystal metal film with adjusted orientation angle.

The heat treatment of the step (I) may include increasing the temperature to 800-1200° C. at the temperature rise rate of 10-50° C./min under an argon gas atmosphere of 100-500 sccm and less than 2 torr, and maintaining the isothermal condition at the increased temperature for 1-4 hours under a hydrogen gas atmosphere of 100-500 sccm and 1 torr or more.

The graphene growth of the step (II) is performed by maintaining the isothermal condition under 0.1 torr or more at 800-1080° C. for 10 minutes to 4 hours under a hydrogen gas atmosphere of 0-1000 sccm and a methane gas atmosphere of 1-10 sccm.

Hereinafter, preparation examples and examples according to the present disclosure will be described in detail together with the accompanying drawings.

### Example 1: Manufacture of Single-Crystal Metal Film by Solid-State Crystal Growth of Seed Crystals

A copper foil (Wellcos, 99.9%, Korea) of 15 μm in thickness and 2 cm×2 cm in width and height is used for a metal precursor. A cold-rolled copper foil (Wellcos, 99.9%, Korea) comprising (111) oriented seeds, having the thickness of 10 μm and the width and length of 1 cm×1 cm as seed crystals is brought into contact with only one surface, i.e., the upper surface of the copper foil by the process of FIG. 4(A) and put into a chamber, and the temperature increases up to 1030° C. at the rate of 30° C./min while maintaining the argon flow rate at 100 sccm and the pressure in the chamber at 0.42 Torr. Subsequently, a heat treatment process is performed by maintaining the isothermal condition at 1030° C. in a hydrogen gas atmosphere (100 sccm, 5 torr) for 2 hours. After the heat treatment process, natural cooling is performed in a hydrogen gas atmosphere (100 sccm, 5 torr) to manufacture a single-crystal metal film with seed crystals comprising (111) oriented seeds embedded therein.

The following Table 1 shows the parameters of the type and contact method of the seed crystals according to examples 1 to 3.

TABLE 1

| Example | Type of seed crystal | Contact method of seed crystal |
|---|---|---|
| Example 1 | Cold-rolled copper foil | One side contact (FIG. 4(A)) |
| Example 2 | Cold-rolled copper foil | Two side contact (FIG. 4(B)) |
| Example 3 | (111) single-crystalline | Press after two side contact |
| | copper foil | (FIG. 4(C)) |

Cold-rolled copper foil: cold-rolled copper foil comprising (111) oriented seeds
The copper foil as the metal precursor is 2 cm × 2 cm in size (width × length)
The copper foil as the seed crystals is 1 cm × 1 cm in size (width × length)
The heat treatment conditions are all the same as example 1

### Comparative Example 1: Manufacture of Single-Crystal Metal Film by Heat Treatment

The same process as example 1 is performed, but heat treatment is only performed, excluding the process of bringing seed crystals into contact with a copper foil. Specifically, the metal precursor of example 1, i.e. the copper foil is put into the chamber, and the temperature increases up to 1030° C. at the rate of 30° C./min while maintaining the argon flow rate at 100 sccm and the pressure in the chamber at 0.42 Torr. Subsequently, the heat treatment process is performed by maintaining the isothermal condition at 1030° C. in a hydrogen gas atmosphere (100 sccm, 5 torr) for 2 hours. After the heat treatment process, natural cooling is performed in a hydrogen gas atmosphere (100 sccm, 5 torr) to manufacture a single-crystal metal film.

FIG. 2(A) is an image showing the crystal structure when normal grain growth and abnormal grain growth occurred in a 15 μm thick copper foil after heat treatment from comparative example 1 of the present disclosure, and FIG. 2(B) shows a result of comparing the single crystallization rate in a 10 μm thick copper foil and a 30 μm thick copper foil heat-treated in the same condition as comparative example 1.

Referring to FIG. 2(A), it can be seen that when single crystallization does not occur and only normal grain growth occurs, a polycrystalline structure with (100) dominant orientation is formed, and when the thermodynamically stable (111) oriented crystals are grown abnormally fast, a single-crystal structure with (111) orientation is obtained.

Additionally, referring to FIG. 2(B), in spite of heat treatment in the same condition, the single crystallization rate of the 10 μm thick copper foil and the 30 μm thick copper foil is 100%, while the single crystallization rate of the 15 μm thick copper foil is very low, and through this, it can be seen that there is no or little thermodynamically stable (111) plane of crystals for abnormal grain growth of single crystals in the copper foil.

FIGS. 4(A) to 4(D) show the contact methods of the seed crystals according to an embodiment of the present disclosure, and FIG. 4(E) shows the single crystallization rate of the single-crystal metal film heat-treated according to the type of the seed crystals and contact method on the 15 μm thick cold-rolled copper foil.

FIGS. 4(A) to 4(C) show three contact methods for bringing the seed crystals into contact with the surface of the copper foil (the metal precursor). FIG. 4(A) shows the contact method for bringing the seed crystals into contact with one surface of the copper foil (the metal precursor), FIGS. 4(B) and 4(C) show the contact method for bringing the seed crystals into contact with two surfaces of the copper foil (the metal precursor), in which the seed crystals are cut in half (0.5 cm) and brought into cross contact with two surfaces of the copper foil (the metal precursor), and in particular, FIG. 4(C) shows the contact method for bringing the seed crystals into cross contact with two surfaces of the copper foil (the metal precursor) as described above and pressing any one surface against the substrate (the alumina plate). The method of FIGS. 4(B) and 4(C) is illustrated in detail in FIG. 4(D), and the metal precursor foil and the seed crystal foil may be attached to each other well through the seed crystal cross contact as shown.

Referring to FIG. 4(E), it can be seen that in the case of the 10 μm thick cold-rolled copper foil, the naturally occurring recrystallized structure strongly suppresses normal grain growth and induces single crystallization 100%, while the 15 μm thick cold-rolled copper foil exhibits the single crystallization rate of 12%. Additionally, in comparison of the single crystallization rate of the single-crystal metal film heat-treated according to the type of seed crystals and the contact method on the 15 μm thick cold-rolled copper foil, the single crystallization rate when the seed crystals are brought into contact with two surfaces of the copper foil (FIG. 4(B)) is higher than the single crystallization rate when the seed crystals are brought into contact with one surface of the copper foil (FIG. 4(A)), and the single crystallization rate when the seed crystals are brought into contact with two surfaces of the copper foil and then pressed (FIG. 4(C)) is much higher than the single crystallization rate when the seed crystals are brought into contact with two surfaces of the copper foil (FIG. 4(B)), and through this, it can be seen that the degree of contact between the metal precursor and the seed crystals is an important single crystallization parameter.

FIG. 5 shows a result of comparing the single crystallization rate in the single-crystal metal film manufactured from example 3 of the present disclosure, and the 10 μm thick copper foil and the 30 μm thick copper foil heat-treated in the same condition as example 3.

Referring to FIG. 5, as opposed to a low single crystallization rate of less than 20% in the 15 μm thick copper foil having undergone only heat treatment in FIG. 2, it can be seen that heat treatment in the same condition after bringing seed crystals into contact leads to a high single crystallization rate of 100%.

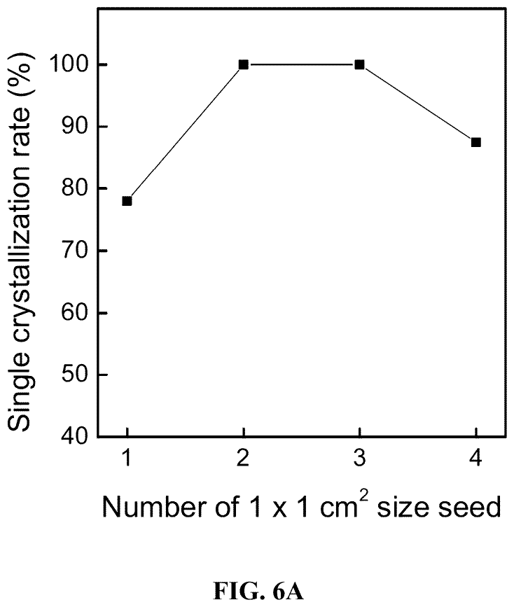

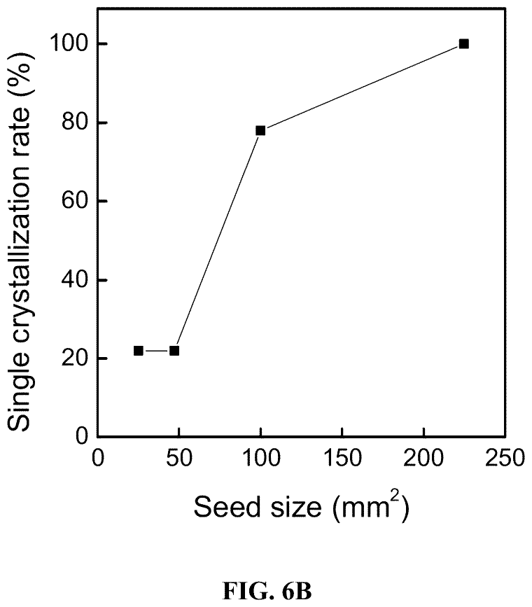

FIG. 6(A) shows the single crystallization rate as a function of the number of seed crystals, and FIG. 6(B) shows the single crystallization rate as a function of the size of the seed crystals, in the process of manufacturing the single-crystal metal film from example 2 of the present disclosure.

Referring to FIG. 6, when the number of seed crystals of 1 cm×1 cm in size increases from 1 to 4, the single crystallization rate tends to improve with the increasing number of seed crystals (FIG. 6(A)), and when the size of the seed crystals increases from 5 mm×5 mm, the single crystallization rate tends to increase, and thus the single crystallization rate of 100% is exhibited at 15 mm×15 mm size (FIG. 6(B)).

Therefore, according to the present disclosure, it is possible to manufacture a single-crystal metal film oriented only in the (111) crystal plane with a high single crystallization rate irrespective of the thickness and shape of the polycrystalline metal precursor by bringing the seed crystals comprising (111) oriented seeds or the (111) single-crystalline seed crystals into contact with the polycrystalline metal precursor and performing heat treatment.

### Example 4: Manufacture of Large-Area Single-Layer Graphene with Adjusted Orientation Angle

A 15 μm thick copper film having undergone (111) orientation and single crystallization through heat treatment is used for seed crystals. The single-crystal seed crystals are divided into pieces and introduced into a 18 μm thick polycrystalline copper film of 8×8 cm in size at a predetermined angle of rotation. Subsequently, after increasing the temperature to 1030° C. at the temperature rise rate of 30° C./min under an argon gas atmosphere of 100 sccm and 0.42 torr, heat treatment is performed while maintaining the isothermal condition at the increased temperature for 2 hours in a hydrogen gas atmosphere of 100 sccm and 5 torr to obtain a single-crystal copper film with adjusted orientation angle.

Large-area single-layer graphene with adjusted orientation angle is manufactured by growing graphene over the total copper area of the single-crystal copper film with adjusted orientation angle while maintaining the isothermal condition at 1020° C. under 3 torr for 20 minutes in a hydrogen gas atmosphere of 50 sccm and a methane gas atmosphere of 1 sccm.

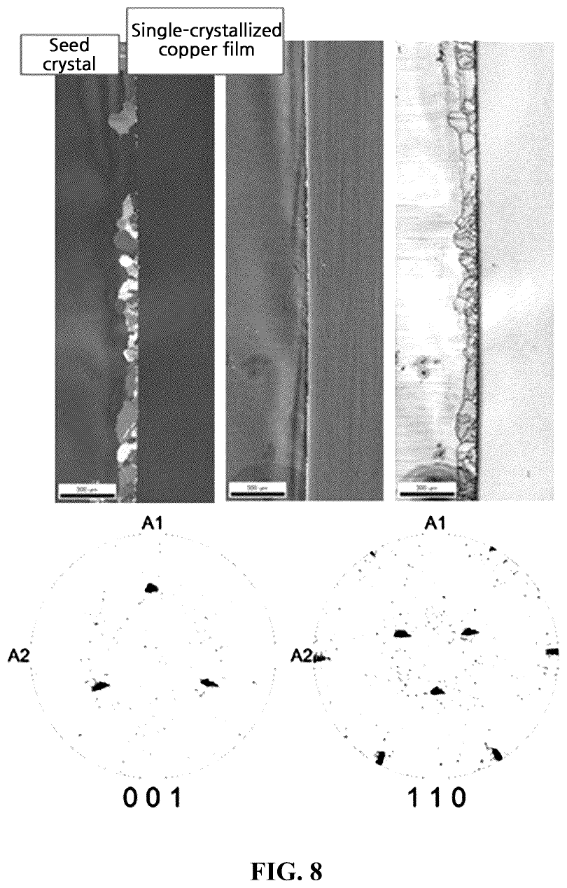

FIG. 8 shows an electron backscatter diffraction (EBSD) and crystal orientation image of the single-crystal copper film by introducing single-crystal seed crystals into the polycrystalline copper film and performing heat treatment according to example 4 of the present disclosure. As shown in FIG. 8, it can be seen that when single-crystal seed crystals are introduced into the polycrystalline copper film before heat treatment and goes through heat treatment, single crystallization occurs in the same crystal orientation as the single-crystal seed crystals.

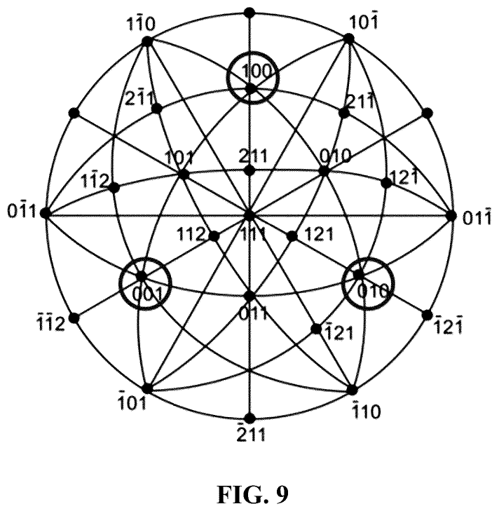

In general, a crystal grain has one orientation, which indicates the crystal plane and arrangement of crystal orientation. The orientation of the metal film may be analyzed through EBSD and a pole figure, and as shown in the (111) standard stereographic projection of FIG. 9, in the case of the single-crystal metal, three (100) peaks form a right triangle. That is, when the metal is a clear single crystal, there are only three (100) peaks, through which orientation may be inferred.

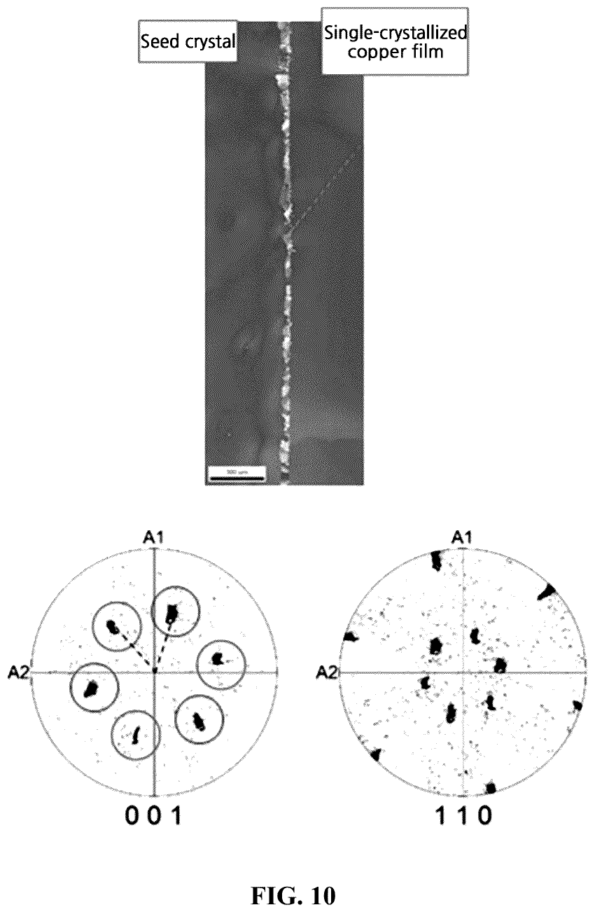

FIG. 10 shows an EBSD image and a pole figure of the boundary including some of the single-crystal seed crystals and parts of the single-crystallized copper film. As shown in FIG. 10, it can be seen that single crystals are on two sides with respect to the boundary, and the single-crystal seed crystals and the single-crystallized copper film have the same crystal orientation through the presence of only three (100) peaks. Additionally, from 6 peaks found in the image of the boundary between the seed crystals and the single-crystallized copper film, it can be seen that the single-crystal seed crystals and the single-crystallized copper film have different crystal orientations. The three peaks in green circles and the three peaks in red circles show different orientations, and it can be seen that the single-crystal seed crystals and the single-crystallized copper film have misorientation of about 60°.

In the case of the existing single crystallization of metal films by heat treatment, single crystals obtained after heat treatment develop the most thermodynamically stable plane, and thus it is possible to predict the oriented crystal planes. However, it is difficult to predict or adjust crystal misorientation occurring in the same (111) plane. When a single-crystal metal film with known crystal misorientation is used for a substrate for growth of 2D nanomaterials, for example, graphene, it is possible to predict the orientation of 2D nanomaterials grown along the crystallographic axis and easily adjust the misorientation between nanomaterials that affect the properties when stacking.

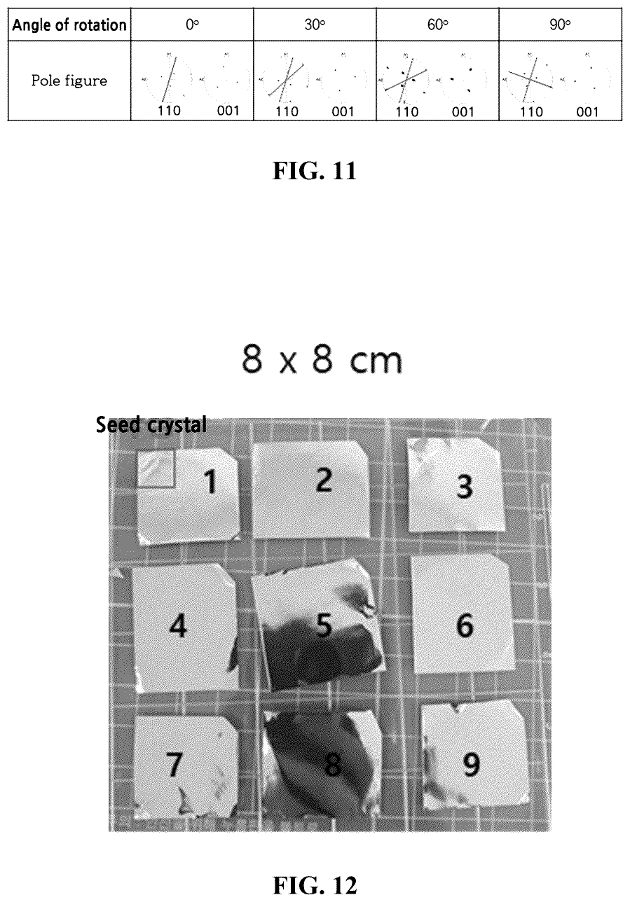

FIG. 11 shows the introduction of seed crystals at a predetermined angle of rotation when the single-crystal copper film is divided into pieces and used as seed crystals according to example 4 of the present disclosure, and as shown in FIG. 11, when the single-crystal copper film is divided into pieces and used as seed crystals, all the divided seed crystals have the same misorientation, and thus it is possible to adjust the misorientation after single crystallization by a simple method of rotating the divided seed crystals. That is, since the polycrystalline base for single crystallization has the same orientation as the crystal plane orientation of the single-crystal seed crystals, the use of the above-described method makes it possible to equally adjust the crystal orientation of another single-crystal metal film or produce single-crystal metal films of desired misorientation.

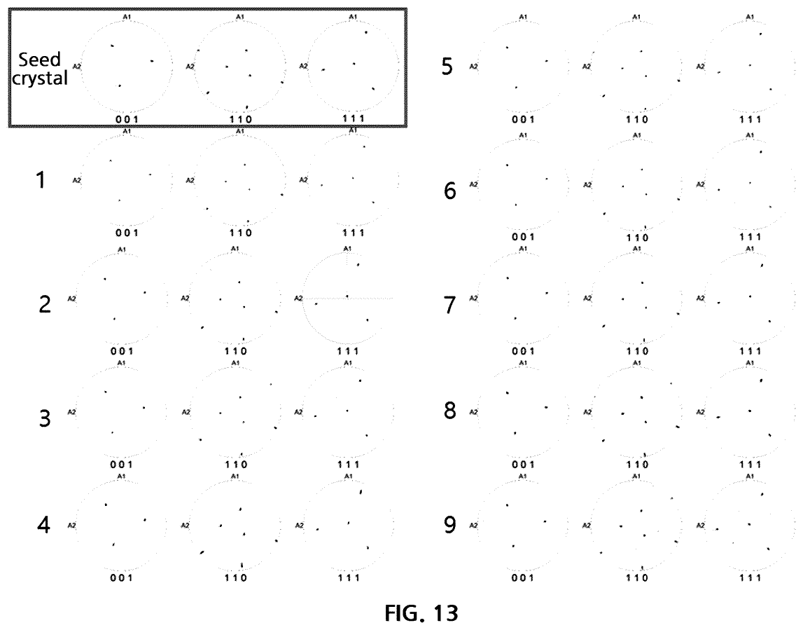

FIG. 12 is an image showing 9 pieces divided to identify the crystal orientation of the single-crystallized copper film according to example 4 of the present disclosure, and FIG. 13 is a pole figure showing the crystal orientation of the single-crystallized copper film divided into 9 pieces shown in FIG. 12, and it can be seen that three (100) peaks are at the identical locations to the seed crystals all over the 9 pieces. It signifies that the single-crystal seed crystals and the single-crystallized copper film have the same crystal orientation, suggesting that in the single crystallization of the copper film through the introduction of the single-crystal seed crystals, it is possible to adjust the crystal orientation of the copper film for single crystallization.

Meanwhile, in the graphene synthesis by a chemical vapor deposition (CVD) method, the growth orientation of graphene is affected by the crystal orientation of the copper substrate. Accordingly, it is possible to adjust the orientation of graphene in the growth of the graphene by adjusting the crystal orientation of the single-crystal copper substrate by the above-described method.

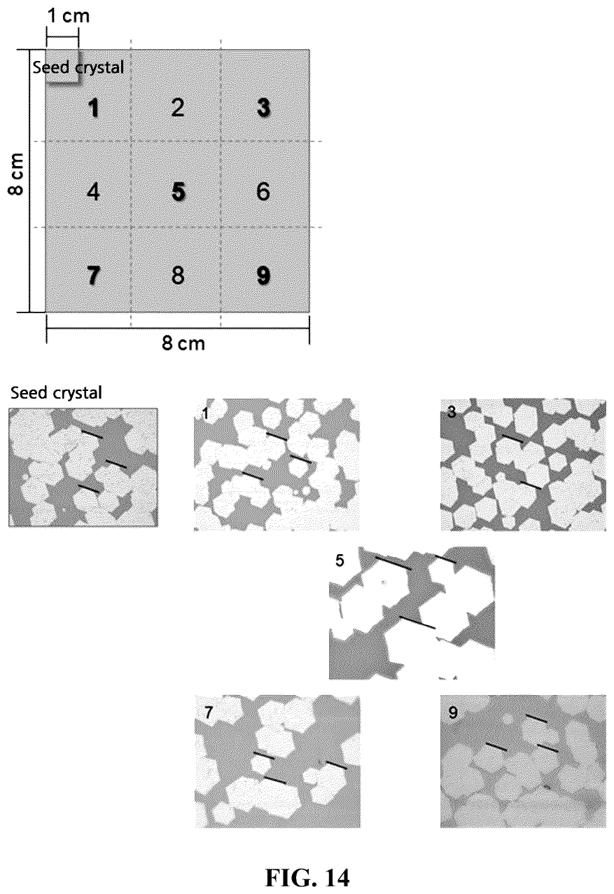

FIG. 14 is an optical electron microscope image of 9 pieces divided after the growth of graphene on the single-crystal metal film with adjusted orientation angle according to example 4 of the present disclosure, showing that the orientation of graphene is identical over the entire area including the locations at which the seed crystals are positioned.

As described above, it is found that in the single crystallization of the polycrystalline copper film, the crystal orientation follows the crystal orientation of the single-crystal seed crystals, and thus it is possible to obtain a single-crystal copper substrate having specific crystal orientation by adjusting the introduction angle of the seed crystals when manufacturing a single-crystal copper substrate by introducing seed crystals having known crystal orientation, and through this, synthesize single-crystal graphene having specific orientation.

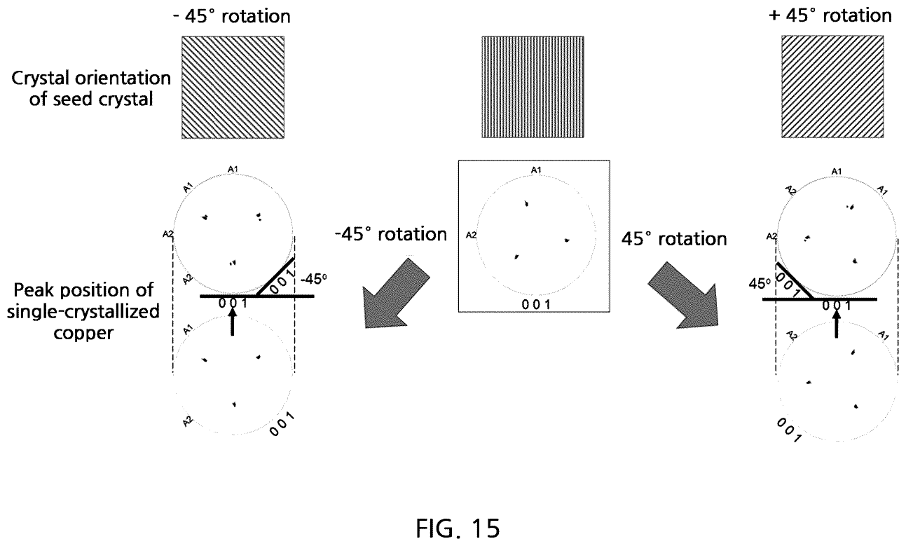

FIG. 15 is an image showing the orientation of the copper film having undergone single crystallization after the introduction of seed crystals having one crystal orientation according to example 4 of the present disclosure by 45° and −45° rotation, and it reveals that in the single crystallization after the introduction of seed crystals having one crystal orientation by 45° and −45° rotation, the orientation of the single-crystallized copper film also has a difference by 45° and −45° along the seed crystals. Through this, it is possible to synthesize large-area graphene having orientation twisted at a specific angle with respect to the orientation of graphene which serves as a reference in the synthesis of graphene by the above-described method.

According to the findings from the recent studies, it has been reported that in the manufacture of double-layer graphene by stacking single-crystal graphene, the electrical properties greatly vary depending on an orientation difference between the two stacked graphene, and it is known that when the orientation between two graphene forms a specific angle (1.1°, a so-called magic angle), superconductivity is manifested. Accordingly, through the above-described method, it is possible to adjust the crystal orientation of the copper substrate and freely adjust the orientation of graphene in the synthesis of the graphene, and accordingly it is possible to produce and stack large-area graphene having a specific angle difference.

Therefore, according to the present disclosure, it is possible to provide multilayer graphene with adjusted orientation angle between graphene by stacking the single-layer graphene manufactured by the method of example 4 of the present disclosure.

1. A single-crystal metal film with seed crystals comprising (111) oriented seeds or (111) single-crystalline seed crystals embedded therein.

2. The single-crystal metal film according to claim 1, wherein the single-crystal metal film includes any one selected from copper (Cu), nickel (Ni), cobalt (Co), iron (Fe), ruthenium (Ru), platinum (Pt), palladium (Pd), gold (Au), silver (Ag), aluminum (Al), chrome (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir) and zirconium (Zr).

3. A conductive film, comprising:
the single-crystal metal film according to claim 1.

4. A substrate for growth of two-dimensional nanomaterials, comprising:
the single-crystal metal film according to claim 1.

5. A method for manufacturing a single-crystal metal film by solid-state crystal growth of seed crystals, comprising:
(a) preparing a polycrystalline metal precursor having various crystal plane orientations such that the crystal planes are not oriented in any one direction, and
(b) bringing seed crystals comprising (111) oriented seeds or (111) single-crystalline seed crystals into contact with a surface of the metal precursor of the step (a) and performing heat treatment.

6. The method for manufacturing a single-crystal metal film by solid-state crystal growth of seed crystals according to claim 5, wherein the seed crystals comprising (111) oriented seeds or the (111) single-crystalline seed crystals is brought into contact with one or two surfaces of the polycrystalline metal precursor and then pressed against a substrate.

7. The method for manufacturing a single-crystal metal film by solid-state crystal growth of seed crystals according to claim 5, wherein two or more seed crystals comprising (111) oriented seeds or two or more (111) single-crystalline seed crystals are brought into contact.

8. The method for manufacturing a single-crystal metal film by solid-state crystal growth of seed crystals according to claim 5, wherein the heat treatment of the step (b) is performed at 800 to 1500° C.

9. A method for manufacturing a single-crystal metal film by solid-state crystal growth of seed crystals, comprising:
(A) attaching seed crystals comprising (111) oriented seeds or (111) single-crystalline seed crystals to a surface of a polycrystalline metal film moving in a roll-to-roll continuous process; and
(B) heat-treating the moving polycrystalline metal film having undergone the step (A),
wherein the polycrystalline metal film of the step (A) has various crystal plane orientations such that the crystal planes are not oriented in any one direction.

10. Large-area single-layer or multilayer graphene with adjusted orientation angle, grown on a single-crystal metal film with adjusted orientation angle having specific crystal orientation.

11. The large-area single-layer or multilayer graphene with adjusted orientation angle according to claim 10, wherein the single-crystal metal film is 15 μm or more in thickness.

12. A method for manufacturing large-area single-layer graphene with adjusted orientation angle, comprising:
(I) introducing single-crystal seed crystals having specific crystal orientation into a polycrystalline metal film at a predetermined angle of rotation and performing heat treatment to obtain a single-crystal metal film with adjusted orientation angle; and
(II) growing graphene on the single-crystal metal film with adjusted orientation angle.

13. The method for manufacturing large-area single-layer graphene with adjusted orientation angle according to claim 12, wherein the heat treatment of the step (I) comprises increasing temperature to 800 to 1200° C. at a temperature rise rate of 10 to 50° C./min under an argon gas atmosphere of 100 to 500 sccm and less than 2 torr, and maintaining isothermal condition at the increased temperature for 1 to 4 hours under a hydrogen gas atmosphere of 100 to 500 sccm and 1 torr or more.

14. The method for manufacturing large-area single-layer graphene with adjusted orientation angle according to claim 12, wherein the graphene growth of the step (II) is performed by maintaining isothermal condition under 0.1 torr or more at 800 to 1080° C. for 10 minutes to 4 hours under a hydrogen gas atmosphere of 0 to 1000 sccm and a methane gas atmosphere of 1 to 10 sccm.

15. Multilayer graphene with adjusted orientation angle between graphene by stacking the single-layer graphene manufactured by the method according to claim 12.
